(19) United States
(12) Patent Application Publication
(10) Pub. No.: US 2016/0268343 A1
(43) Pub. Date: Sep. 15, 2016

(54) VARIABLE RESISTANCE MEMORY DEVICE AND MANUFACTURING METHOD THEREOF

(71) Applicant: KABUSHIKI KAISHA TOSHIBA, Minato-ku (JP)

(72) Inventor: Kikuko SUGIMAE, Kuwana (JP)

(73) Assignee: KABUSHIKI KAISHA TOSHIBA, Minato-ku (JP)

(21) Appl. No.: 14/847,520

(22) Filed: Sep. 8, 2015

Related U.S. Application Data
(60) Provisional application No. 62/131,587, filed on Mar. 11, 2015.

(51) Int. Cl. H01L 27/24; H01L 45/00

(52) U.S. Cl. CPC H01L 27/2463; H01L 45/1233; H01L 45/1608; H01L 45/1666

(57) ABSTRACT

A resistance variable memory has a memory cell area, a plurality of first wires arranged at intervals in a first direction in the memory cell area and arranged at intervals in a laminating direction, a plurality of second wires arranged at intervals in a second direction in the memory cell area and alternatively arranged with the first wires in a laminating direction, memory cells arranged at each crossing point between the first wire and the second wire in the memory cell area and include variable resistance elements, a first wire interconnecting area arranged separately from the memory cell area and in which conductive layers electrically conducting with the plurality of first wires are arranged, and a second wire interconnecting area arranged separately from the memory cell area and the first wire interconnecting area and in which conductive layers electrically conducting with the plurality of second wires are arranged.

### CROSS REFERENCE TO RELATED APPLICATIONS

This application is based upon and claims the benefit of priority from the prior U.S. Provisional Patent Application No. 62/131,587 filed on Mar. 11, 2015, the entire contents of which are incorporated herein by reference.

### FIELD

An embodiment of the present invention relates to a resistance variable memory and a manufacturing method for the resistance variable memory.

### BACKGROUND

Recently, a resistance variable memory which uses a variable resistance element as a storage element is focused as a next-generation nonvolatile memory alternative to flash memory. The resistance variable memory does not need a transistor to store data in a storage layer and can form a memory cell including the storage layer in a crossing area of a bit line and a word line, and therefore it is easy to be miniaturized. Therefore, it is being considered that bit lines and word lines are three-dimensionally laminated to improve an integration degree.

In the case where the bit lines and the word lines are three-dimensionally arranged, it is necessary to secure a wiring area for connecting the bit lines and the word lines on a semiconductor substrate. When bit lines and word lines on each layer are separately interconnecting on a semiconductor substrate, a ratio of the wiring area with respect to a memory cell area on a substrate surface is increased, and an integration degree cannot be increased.

### BRIEF DESCRIPTION OF THE DRAWINGS

FIG. 1 is a block diagram illustrating an internal configuration of a resistance variable memory according to an embodiment.

FIG. 2 is an equivalent circuit diagram of a memory cell array.

FIG. 3 is a sectional view illustrating an example of a layer configuration of a memory cell.

FIG. 4 is a schematic layout diagram around a memory cell area of the resistance variable memory according to the embodiment.

FIG. 5 is a schematic perspective view around the memory cell area of the resistance variable memory according to the embodiment.

FIG. 6 is a view schematically illustrating a sectional structure of an A-A line cross section illustrated in FIG. 5.

FIG. 7 is a view schematically illustrating a sectional structure of a B-B line cross section illustrated in FIG. 5.

FIG. 8 is a view illustrating an example in which bit lines BL of four layers adjacent in a laminating direction connect to four bit line interconnecting portions on a right side.

FIG. 9 is a view illustrating an example in which the word lines WL of four layers adjacent in a laminating direction connect to one word line interconnecting portion on a right side.

FIGS. 10A to 10I are views describing a manufacturing process for a bit line interconnecting portion.

FIGS. 11A to 11H are views describing a manufacturing process for a word line interconnecting portion.

FIG. 12 is a plan view of a bit line interconnecting area.

### DETAILED DESCRIPTION

A resistance variable memory according to one embodiment has a memory cell area arranged on a substrate, a plurality of first wires arranged at intervals in a first direction in the memory cell area and arranged at intervals in a laminating direction, a plurality of second wires arranged at intervals in a second direction in the memory cell area and alternatively arranged with the first wires in a laminating direction, memory cells which are arranged at each crossing point between the first wire and the second wire in the memory cell area and include variable resistance elements, a first wire interconnecting area arranged separately from the memory cell area on the substrate and in which conductive layers electrically conducting with the plurality of first wires are arranged, and a second wire interconnecting area arranged separately from the memory cell area on the substrate and the first wire interconnecting area and in which conductive layers electrically conducting with the plurality of second wires are arranged.

The first wire interconnecting area comprises the plurality of first wire interconnecting portions electrically conducting with each of the plurality of first wires.

Each of the plurality of first wire interconnecting portions comprises a first laminated body including a first conductive portion electrically conducting with a corresponding first wire, and a second conductive portions including conductive layers for a total number of the second wires and the first wires arranged on the substrate side from the corresponding first wire.

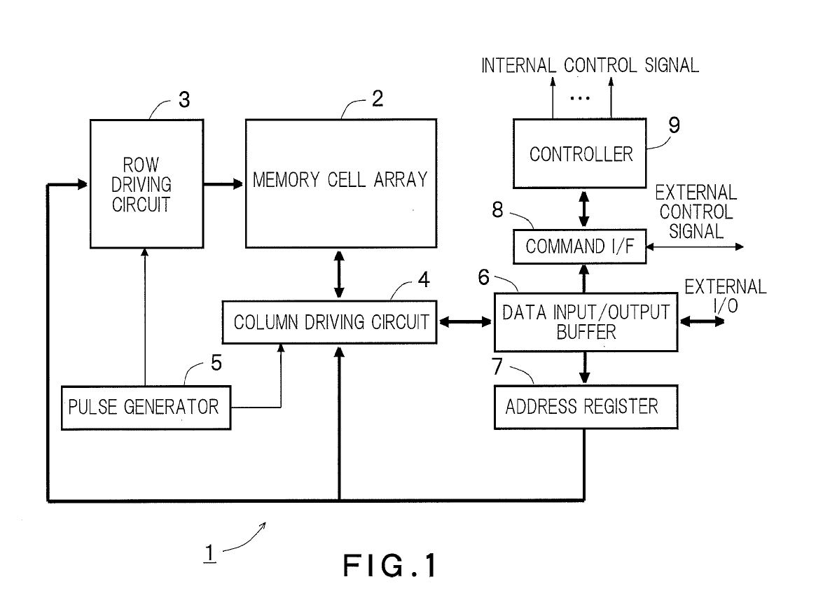

An embodiment will be described below with reference to the figures. FIG. 1 is a block diagram illustrating an internal configuration of a resistance variable memory 1 according to the embodiment. The resistance variable memory 1 illustrated in FIG. 1 includes a memory cell array 2, a row driving circuit 3, a column driving circuit 4, a pulse generator 5, a data input/output buffer 6, an address register 7, a command interface (command I/F) 8, and a controller 9. A configuration omitted in FIG. 1 may be included in the resistance variable memory 1. A characteristic configuration in the resistance variable memory 1 will be mainly described below.

The memory cell array 2 includes multiple memory cells three-dimensionally arranged. Each of the memory cells is a resistance variable memory cell including a current rectifying element and a variable resistance element. However, each memory cell does not necessarily include the current rectifying element.

The row driving circuit 3 controls electric potential of multiple word lines arranged in the memory cell array 2. In the present description, a direction in which the multiple word lines extend is called a row direction.

The column driving circuit 4 controls electric potential of multiple bit lines arranged in the memory cell array 2. In the present description, a direction in which the multiple bit lines extend is called a column direction.

The pulse generator 5 generates a pulse signal synchronized with a timing at which the row driving circuit 3 and the column driving circuit 4 control electric potential of word lines and bit lines.

The data input/output buffer 6 is connected to a host device (not illustrated) via an external I/O line. The data input/output buffer 6 receives write data, an address, and a command from the external I/O line and sends, to the external I/O line, data read from a memory cell. The data input/output buffer 6 sends, to the address register 7, the address received from the. external I/O line. The address register 7 sends the received address to the row driving circuit 3 and the column driving circuit 4. Further, the data input/output buffer 6 sends, to the column driving circuit 4, the data received from the external I/O line.

The command I/F 8 receives an external control signal from the outside and determines based on the external control signal whether the data input/output buffer 6 has received any of write data, an address, and a command from the outside. The command I/F 8 sends, to the controller 9, the command received from the external I/O by the data input/output buffer 6.

The controller 9 integrally controls the resistance variable memory 1. For example, the controller 9 controls writing, reading, and erasing of a memory cell based on a command from a host device. More specifically, the controller 9 selectively drives a word line and a bit line adjacent in a laminating direction.

Each transistor included in a peripheral circuit other than the memory cell array 2 in the resistance variable memory 1 is formed on a semiconductor substrate arranged on a lower side of the three-dimensionally laminated memory cell array 2. The semiconductor substrate is, for example, a silicon substrate.

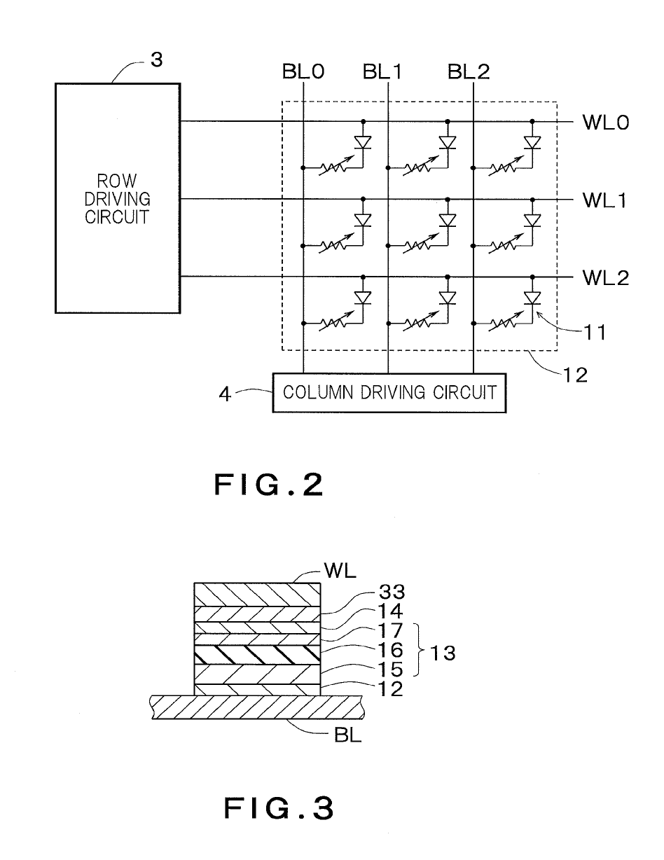

FIG. 2 is an equivalent circuit diagram of the memory cell array 2. As illustrated in FIG. 2, multiple bit lines BL0, BL1, BL2 . . . (hereinafter collectively called the bit line BL) and multiple word lines WL0, WL1, WL2 . . . (hereinafter collectively called the word line WL) are arranged in a crossing direction, and the memory cell 11 is arranged in each crossing area of multiple bit lines BL and multiple word lines WL. Specifically, the resistance variable memory 1 according to the embodiment is a cross-point type resistance variable memory. In the present description, a direction in which the multiple bit lines BL extend is called a column direction, and a direction in which the multiple word lines WL extend is called a row direction.

The memory cell 11 has a configuration in which a variable resistance element and a current rectifying element are connected in series. The variable resistance element and the current rectifying element are not necessarily formed by a separate layer. For example, in a memory cell including an upper electrode layer, an ion supply layer, a resistance change layer, and a lower electrode layer, to be described in detail below, the ion supply layer and the resistance change layer have functions of the variable resistance element and the current rectifying element, and therefore the current rectifying element such as a diode is not necessarily separately formed.

When a potential difference between the bit line BL and the word line WL reaches a predetermined writing voltage, a variable resistance element is brought into a low resistance state. This operation is called a set operation. In addition, when a predetermined voltage in a direction reverse to a writing direction is applied to the bit line BL and the word line WL connected to the memory cell 11 including a variable resistance element in a low resistance state, the variable resistance element returns to an original high resistance state. This operation is called a reset operation. When data in the memory cell 11 is read out, a predetermined reading voltage lower than a writing voltage is applied between the word line WL and the bit line BL to determine from a current value flowing to the memory cell whether the memory cell is in a low resistance state or in a high resistance state.

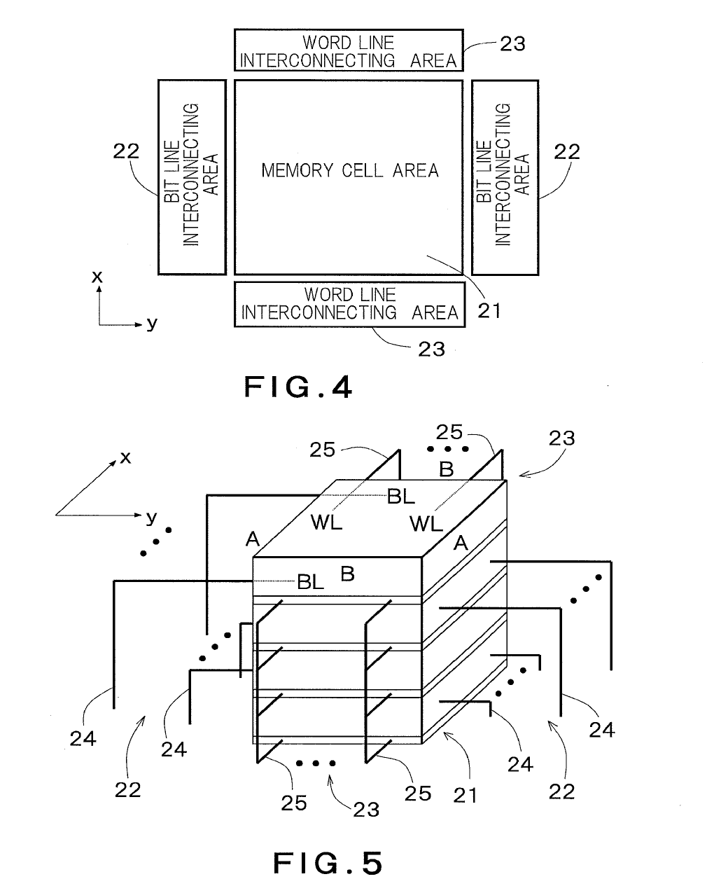

FIG. 3 is a sectional view illustrating an example of a layer configuration of the memory cell 11. FIG. 3 illustrates the bit line BL and the word line WL arranged on an upper side of the bit line BL. Actually, the memory cell 11 is also arranged on a lower side of the bit line BL. In the memory cell 11 on a lower side and an upper side of the bit line BL, a lower electrode layer 12, a variable resistance element (first variable resistance element) 13, an upper electrode layer 14, and a stopper layer 15 are arranged in a lamination order toward the word line WL on a lower side and an upper side from the bit line BL. The lower and upper electrode layers 12 and 14 function as a barrier metal and an adhesive layer, and for example, titanium, titanium nitride, tantalum nitride, and tungsten nitride are used as materials thereof. The materials of these electrode layers may be the same or different. Further, the electrode layers may be formed by multiple layers including different elements. In the present description, the lower electrode layer 12, the variable resistance element (first variable resistance element) 13, and the upper electrode layer 14 are called a memory cell layer 10.

More specifically, the variable resistance element 13 includes a counter electrode layer 16, a resistance change layer 17, and an ion supply layer 18 in a lamination order toward the word line WL on a the lower side (upper side) from the bit line BL. The ion supply layer 18 is a layer including a metallic element such as silver and copper. The resistance change layer includes a single layer or multiple layers of such as amorphous silicon, a silicone oxide film, a silicon nitride film, hafnium oxide, and zirconium oxide. The counter electrode layer 16 includes such as amorphous silicon, polysilicon, tantalum nitride, tantalum nitride silicon, and aluminum nitride. The counter electrode layer 16 may be integrated with the above-described lower electrode layer 12. When a positive voltage is applied from the ion supply layer 18 to the counter electrode layer 16 (hereinafter, this direction is called an order direction) with respect to the memory cell 11, for example, ionized metallic elements move in the resistance change layer 17 from the ion supply layer 18. The ionized metallic elements are reduced by electrons supplied from the counter electrode 15 side, and a filament including metallic elements is formed in the resistance change layer 17. When the filament sufficiently increases in size in a film thickness direction, a resistance of the memory cell is lowered, and the memory cell is brought into a low resistance state. On the other hand, when a negative voltage is applied in the order direction, metallic elements included in a filament on the lower electrode 12 side are, for example, ionized and moved to the ion supply layer 18 side by an electric field applied in a negative direction. When the filament is eliminated from the resistance change layer 17, a resistance of the memory cell 11 is increased and brought into a high resistance state. These two states are denoted as “0” and “1” and used in storage operating principles of the resistance variable memory 1. Although it has been described that metallic elements have ionized, the metallic elements may simply form a filament by diffusion. Further, by selecting an appropriate combination among the ion supply layer 18, the resistance change layer 17, and the counter electrode layer 16, a function of a rectifying element can be imparted to the memory cell 11. For example, when a positive voltage in the order direction is less than a predetermined applied voltage, a metal filament formed in the resistance change layer 17 is shortened. Specifically, a gap between the filament and the counter electrode layer 15 widens. More specifically, since the gap between the filament and the counter electrode layer becomes longer, a current flowing to the memory cell 11 decreases when an applied voltage is less than a certain level, and the memory cell 11 is brought into a high resistance state. Therefore, when a voltage is applied in a negative direction after a set operation, the reset operation is performed in the resistance change layer 17 at a low current level. As described above, the memory cell 11 indicates a characteristic as if the variable resistance element 13 and a current rectifying element are connected in series.

A structure of a memory cell having functions of the variable resistance element 13 and a current rectifying element has been described. However, a memory cell may have a structure in which each of the variable resistance element 13 and the current rectifying element is separately formed and arranged in series. In this case, a type of the variable resistance element 13 may not be specified if a resistance can be changed by voltage application via such as current, heat, and chemical energy. As a current rectifying element, for example, a diode formed of polysilicon is used. As a specific example of a diode, a PIN diode can be used which includes a p-type layer and an n-type layer including impurities, and an intrinsic layer inserted between the p-type layer and the n-type layer and not including impurities. In addition, each type of diodes such as a PN junction diode, which includes the p-type layer and the n-type layer, and a Schottky diode, and a punch-through diode can be used as the diode.

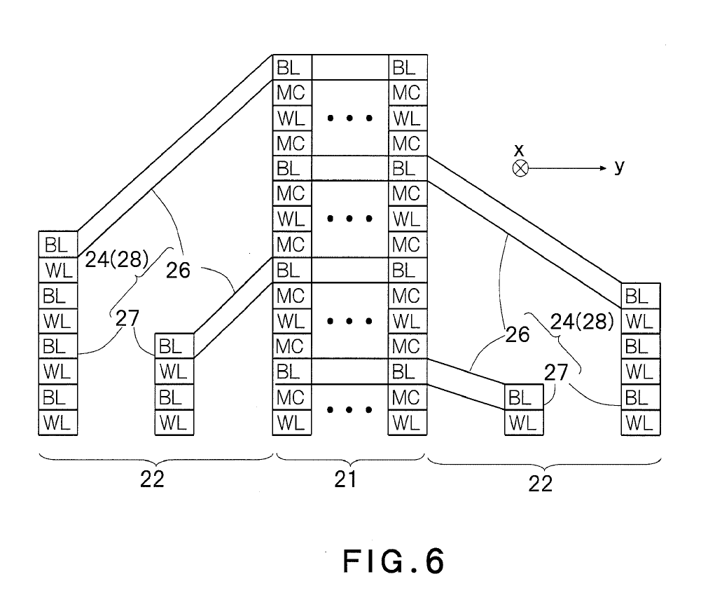

FIG. 4 is a schematic layout diagram around the memory cell area 21 of the resistance variable memory according to the embodiment. In FIG. 4, a bit line is arranged separately in a first direction x, and a word line is arranged separately in a second direction y. As illustrated in FIG. 4, a bit line interconnecting area 22 is provided on both sides of the second direction y across the memory cell area 21, and a word line interconnecting area 23 is provided on both sides in the first direction x across the memory cell area 21. The memory cell area 21, the bit line interconnecting area 22, and the word line interconnecting area 23 are arranged via an interlayer insulating film on an upper side of a semiconductor region in which such as a hook up transistor (not illustrated) is formed. Hereinafter, a baking surface in which the memory cell area 21, the bit line interconnecting area 22, and the word line interconnecting area 23 are formed is called a substrate surface. Multiple memory cells 11 are arranged in a surface direction and also in a laminating direction in the memory cell area 21 on the substrate surface. Further, multiple bit line interconnecting portions are separately arranged in a surface direction to the bit line interconnecting area 22 on the substrate surface. These bit line interconnecting portions extend in a laminating direction. Similarly, at least one bit line interconnecting portion is arranged in the word line interconnecting area 23 on the substrate surface, and the bit line interconnecting portion extends in a laminating direction.

Among multiple bit lines laminated in the memory cell area 21, bit lines in even-numbered layers are interconnected in one side of the bit line interconnecting areas 22, and bit lines in odd-numbered layers are interconnected in the other side of the bit line interconnecting areas 22.

Further, among multiple word lines laminated in the memory cell area 21, word lines in even-numbered layer are interconnected in one side of the word line interconnecting areas 23, and word lines in odd-numbered layers are interconnected in the other side of the word line interconnecting areas 23.

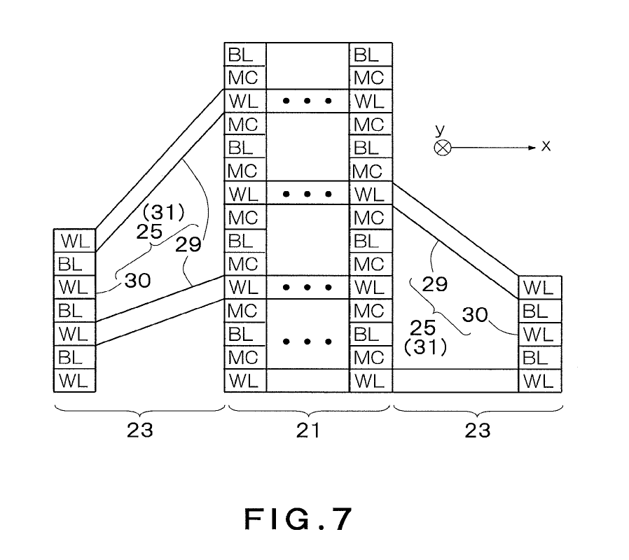

FIG. 5 is a schematic perspective view around the memory cell area 21 of a resistance variable memory according to the embodiment. FIG. 5 illustrates an example in which the memory cells 11 of four layers are laminated in a layer direction. However, the number of laminations is arbitrary. In FIG. 5 as with FIG. 4, a direction in which multiple bit lines BL are arranged on the same layer is a first direction x, a direction in which the bit lines BL extend is a second direction y, a direction in which multiple word lines WL arranged is the second direction y, and a direction in which the word lines WL extend is the first direction x.

The bit lines BL and the word lines WL are alternatively arranged in a laminating direction. The memory cells 11 are arranged at crossing points of the bit lines BL and the word lines WL. In FIG. 5, a memory cell 11 group arranged on a surface is indicated by one rectangle. The bit line BL is arranged in the rectangle. Hereinafter, a conductor interconnected from each bit line BL is called a bit line interconnecting portion 24, and a conductor interconnected from each word WL is called a word line interconnecting portion 25.

As illustrated in FIG. 5, all bit lines BL are individually interconnected with the bit line interconnecting area 22. More specifically, multiple bit line interconnecting portions 24 are provided in each of two bit line interconnecting areas 22 arranged on both sides of the second direction y in which each bit line BL extends. Each of multiple bit line interconnecting portions 24 in one side of the bit line interconnecting areas 22 is electrically conducted with any of bit lines BL in even-numbered layers. Each of multiple bit line interconnecting portions 24 in the other side of the bit line interconnecting areas 22 is electrically conducted with any of bit lines BL in even-numbered layers.

Further, the word lines WL in even-numbered layers among multiple word lines WL in a laminating direction are connected to the common word line interconnecting portion 25 in one side of the word line interconnecting areas 23. Furthermore, word lines WL in odd-numbered layers among multiple word lines WL in a laminating direction are connected to the common word line interconnecting portion 25 in the other side of the word line interconnecting areas 23.

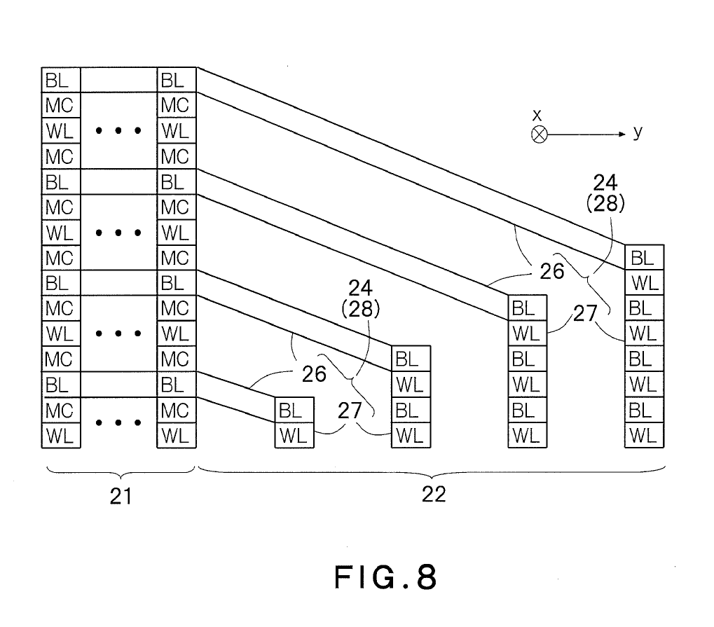

FIG. 6 is a view schematically illustrating a sectional structure of an A-A line cross section illustrated in FIG. 5. A horizontal direction in FIG. 6 is the second direction y in which the bit line BL extends. In an example illustrated in FIG. 6, the multiple bit line interconnecting portions (first wire interconnecting portions) 24 electrically conducted with the bit lines BL in odd-numbered layers are arranged in the bit line interconnecting area (first wire interconnecting area) 22 on a right side in the memory cell area 21. The multiple bit line interconnecting portions (first wire interconnecting portions) 24 electrically conducted with the bit lines BL in even-numbered layers are arranged in the bit line interconnecting area (first wire interconnecting area) 22 on a left side in the memory cell area 21.

Each of the bit line interconnecting portions 24 includes a first laminated body 28 including a first conductive portion 26 electrically conducted with a corresponding bit line BL and a second conductive portion 27 including conductive layers for the total number of the word lines WL and the bit lines BL arranged on a substrate surface side from the corresponding bit line BL.

As described below, each conductive layer included in the second conductive portion 27 is sequentially formed in a process for laminating the word lines WL and the bit lines BL in the memory cell area 21. Therefore, a thickness of each conductive layer in the second conductive portion 27 is almost the same as the thickness of a corresponding word line WL or bit line BL. The first conductive portion 26 is also formed in a process for forming a corresponding bit line BL. Therefore, the thickness of the first conductive portion 26 is almost the same as the thickness of the corresponding bit line BL.

In this manner, a first laminated body 28 in the bit line interconnecting portion 24 is formed together in a process for laminating the memory cell 11 in the memory cell area 21, and therefore a separate process for forming the first laminated body 28 is not needed. Further, the first laminated body 28 is formed by materials of the bit line BL and the word line WL, and therefore the same electrical characteristics as those of the bit line BL and the word line WL are secured.

The height of the first laminated body 28 becomes low as approaching to the memory cell area 21, and the height becomes high as being far from the memory cell area 21. A laminated body close to the memory cell area 21 includes the first conductive portion 26 electrically conducted with the bit line BL on a lower layer side.

By lowering the height of a laminated body closer to the memory cell area 21, the first conductive portion 26 extending from each first laminated body 28 does not come into contact to the laminate, and therefore laminated bodies can be closely arranged each other at narrow intervals, and a size of the bit line interconnecting area 22 can be reduced.

The first laminated bodies 28 in the bit line interconnecting area 22 are arranged in the second direction y illustrated in FIG. 6, and also the multiple first laminated bodies 28 are arranged at intervals in the first direction x (front and back directions on a paper of FIG. 6). Interlayer insulating films (not illustrated) cover intervals between laminated bodies.

In FIG. 6, the first conductive portion 26 and the second conductive portion 27 included in each of first laminated bodies 28 in the bit line interconnecting area 22 are denoted as BL or WL for simplification. BL indicates the first conductive portion 26 or the second conductive portion 27 formed when the bit lines BL in the same layer is formed. WL indicates the second conductive portion 27 formed when the word lines WL in the same layer is formed. Further, the first conductive portion 26 includes an interconnecting area extending to a corresponding word line WL.

In this manner, the first laminated body 28 corresponding to the bit line interconnecting portion 24 is formed by laminating the multiple second conductive portions 27 for the total number of the word lines WL and the bit lines BL arranged at a lower side than corresponding bit lines BL in the memory cell area 21. Therefore, a contact having a high conductivity can be formed by a simple method.

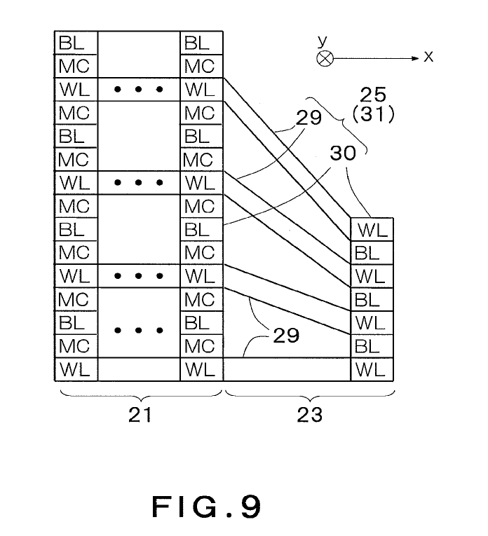

FIG. 7 is a view schematically illustrating a sectional structure of a B-B line cross section illustrated in FIG. 5. A horizontal direction in FIG. 7 is the first direction x. In an example illustrated in FIG. 7, a word line interconnecting area (second wire interconnecting portion) 25 electrically conducted with the word lines WL in odd-numbered layers are arranged in the word line interconnecting area (second wire interconnecting area) 23 on a right side in the memory cell area 21. The word line interconnecting portions (second wire interconnecting portions) 25 electrically conducted with the word lines WL in even-numbered layers are arranged in the word line interconnecting area (second wire interconnecting area) 23 on a left side in the memory cell area 21.

The word line interconnecting portion 25 on the right side includes a second laminated body 31 including a third conductive portion 29 electrically conducted with the word lines WL in odd-numbered layers and a fourth conductive portion 30 including conductive layers for the total number of the word lines WL and the bit lines BL arranged on a substrate surface side from the word lines WL in odd-numbered layers.

The word line interconnecting portion 25 on the left side includes a second laminated body 31 including a third conductive portion 29 electrically conducted with the word lines WL in odd-numbered layers and a fourth conductive portion 30 including conductive layers for the total number of the word lines WL and the bit lines BL arranged on a substrate surface side from the word lines WL in even-numbered layers.

As described below, each conductive layer included in the fourth conductive portion 30 is sequentially formed in a process for laminating the word lines WL and the bit lines BL in the memory cell area 21. Therefore, a thickness of each conductive layer in the fourth conductive portion 30 is almost the same as the thickness of a corresponding word line WL or bit line BL. The third conductive portion 29 is also formed in a process for forming a corresponding word line WL. Therefore, the thickness of the third conductive portion 29 is almost the same as the thickness of the corresponding word line WL.

In this manner, as with the first laminated body 28, the second laminated body 31 in the word line interconnecting portion 25 is formed together in a process for laminating the memory cells 11 in the memory cell area 21, and therefore a separate process for forming the second laminated body 31 is not needed. Further, as with the first laminated body 28, the second laminated body 31 is formed by materials of the bit line BL and the word line WL, and therefore the same electrical characteristics as those of the bit line BL and the word line WL are secured.

In the bit line interconnecting area 22, the bit line interconnecting portion 24 is separately provided to each bit line BL in a laminating direction. In the word line interconnecting area 23, multiple word lines WL in a laminating direction can be connected to the common word line interconnecting portion 25. Therefore, the total number of the word line interconnecting portions 25 can be reduced, and a size of the word line interconnecting area 23 can be decreased.

For example, in an example illustrated in FIG. 7, the second laminated body 31 in the word line interconnecting portion 25 on a right side is electrically conducted with the word lines WL in first and third layers. Further, the second laminated body 31 in the word line interconnecting portion 25 on a left side is electrically conducted with the word lines WL in second and fourth layers. Accordingly, the word lines WL divided into four layers can be connected collectively to the two second laminated bodies 31, and the number of the second laminated bodies 31 can be reduced.

The above-described FIGS. 6 and 7 illustrate that laminated bit lines BL and word lines WL are connected to corresponding bit line interconnecting portions 24 and word line interconnecting portions 25 on the left and right sides. However, multiple bit lines BL and word lines WL adjacent in a laminating direction can be connected to the bit line interconnecting portion 24 or the word line interconnecting portion 25 on one direction without dividing to odd-numbered and even-numbered layers.

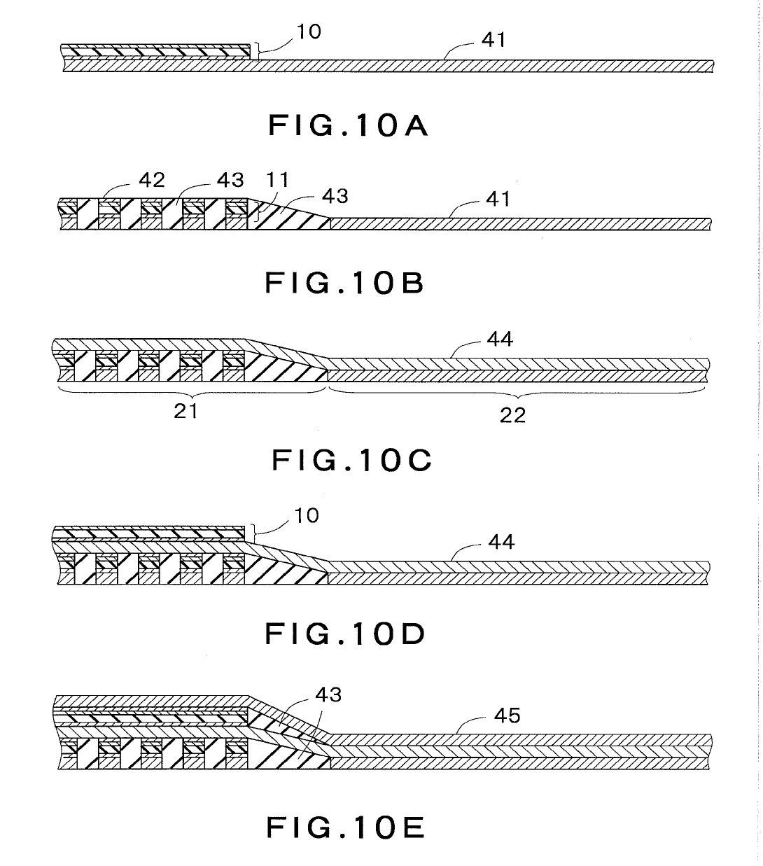

FIG. 8 is a view illustrating an example in which the bit lines BL of four layers adjacent in a laminating direction connect to four bit line interconnecting portions 24 on a right side. In the example illustrated in FIG. 8, four bit line interconnecting portions 24 are arranged in the second direction y. As the bit line interconnecting portion 24 becomes more distant from the memory cell area 21, the height of the first laminated body 28 becomes higher at the bit line interconnecting portion so as to electrically conduct with the bit line BL on an upper layer side.

In an example illustrated in FIG. 8, the first laminated body 28 closest to the memory cell area 21 is connected to the bit line BL in a first layer, the first laminated body 28 second closest thereto is connected to the bit line BL in a second layer, the first laminated body 28 third closest thereto is connected to the bit line BL in a third layer, and the first laminated body 28 farthest from the memory cell area 21 is connected to the bit line BL in a fourth layer.

In contrast to FIG. 8, the bit lines BL of four layers may be connected to the four bit line interconnecting portions 24 on a left side from the memory cell area 21. Further, two or more bit lines BL adjacent in a laminating direction is set as a unit and may be alternatively connected to the right and left bit line interconnecting portions 24.

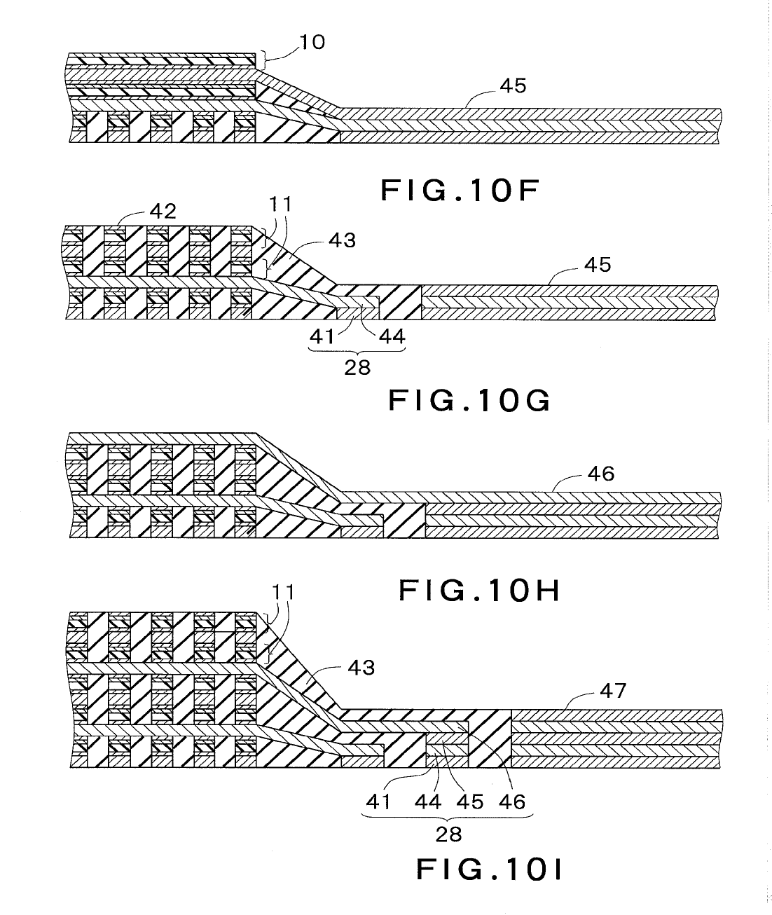

FIG. 9 is a view illustrating an example in which the word lines WL of four layers adjacent in a laminating direction connect to one word line interconnecting portion 25 on a right side. The second laminated body 31 in the word line interconnecting portion 25 illustrated in FIG. 9 has a structure in which total eight conductive layers (third and fourth conductive layers) corresponding to four word lines WL and four bit lines BL in a laminating direction in the memory cell area 21 are laminated, and the second laminated body 31 electrically conducts with four word lines WL.

As illustrated in FIG. 9, in the case where the word lines WL in odd-numbered layers and even-numbered layers are connected to one second laminated body 31, a number of the second laminated body 31 can be reduced, and a size of the word line interconnecting area 23 can be further reduced.

In contrast to FIG. 9, the word lines WL of four layers may be connected to the word line interconnecting portion 25 on a left side from the memory cell area 21. Further, two or more word lines WL adjacent in a laminating direction is set as a unit and may be alternatively connected to the right and left word line interconnecting portions 25.

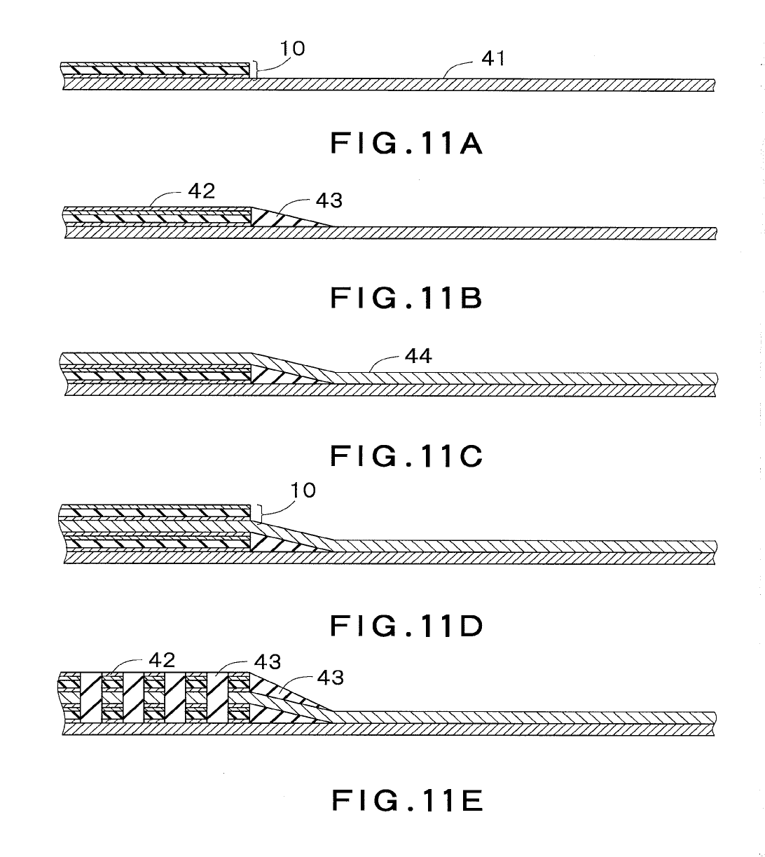

FIGS. 10A to 10I are views describing a manufacturing process for the bit line interconnecting portion 24. As described above, the bit line interconnecting portion 24 can be formed together in a process for forming the memory cell 11.

First, as illustrated in FIG. 10A, a first metal layer 41 for a word line WL on the lowest layer is formed on a substrate surface, and a memory cell layer 10 is formed thereon. A material of each metal layer for a bit line and a word line, to be described later, including the first metal layer 41 are, for example, W, WSi, NiSi, and CoSi. Herein, the memory cell layer 10 is a lamination film including the lower electrode layer 12, the variable resistance element 13, and the upper electrode layer 14, illustrated in FIG. 3. The memory cell layer 10 is formed in the memory cell area 21 and not formed in the bit line interconnecting area 22.

Next, as illustrated in FIG. 10B, after a dummy metal layer 42 is formed on the memory cell layer 10 and the first metal layer 41, the memory cell 11 of one layer is formed by patterning the memory cell area 21 by applying a register (not illustrated), and an interlayer insulating film 43 is formed between adjacent memory cells 11. Further, the interlayer insulating film 43, in which a surface is inclined, is formed between the memory cell area 21 and the bit line interconnecting area 22.

Next, as illustrated in FIG. 10C, a second metal layer 44 for the bit line BL is formed on the dummy metal layer 42 and the interlayer insulating film 43. The second metal layer 44 is closely arranged on the first metal layer 41 in the bit line interconnecting area 22.

Next, as illustrated in FIG. 10D, the memory cell layer 10 in a second layer is formed on the second metal layer 44 in the memory cell area 21.

Next, as illustrated in FIG. 10E, the dummy metal layer 42 is formed on the memory cell layer 10 in the second layer, also the interlayer insulating film 43 is formed between the memory cell area 21 and the bit line interconnecting area 22, and a third metal layer 45 for the word line WL in a second layer is formed thereon. The third metal layer 45 is closely arranged on the second metal layer 44 in the bit line interconnecting area 22.

Next, as illustrated in FIG. 10F, the memory cell layer 10 in a third layer is formed on the third metal layer 45 in the memory cell area 21.

Next, as illustrated in FIG. 10G, the dummy metal layer 42 is arranged on the third metal layer 45, and the memory cell layer 10 is patterned by applying a photoresistor (not illustrated) thereon. As a result, the memory cells 11 in second and third layers are formed in the memory cell area 21. Further, between the memory cells 11 adjacent to a substrate surface direction, the interlayer insulating film 43 is formed, and the third metal layer 45 arranged between the memory cell area and the bit line interconnecting area 22 is removed. Furthermore, the first laminated body 28 in the bit line interconnecting portion 24 connected to the bit line BL in a first layer is formed, and the interlayer insulating film 43 covers around the first laminated body 28. As illustrated in FIG. 10G, the first laminated body 28 has a two-layer structure, in which the second metal layer 44 of which material is the same as that of the bit line BL in the lowest layer is laminated on the first metal layer 41 of which material is the same as that of the word line WL in the lowest layer.

Next, as illustrated in FIG. 10H, a fourth metal layer 46, which becomes the bit line BL in a second layer, is formed on an upper surface of the memory cell 11 of the memory cell layer 10 in a third layer and the interlayer insulating film 43. The fourth metal layer 46 is closely arranged on the third metal layer 45 in the bit line interconnecting portion 24.

Then, after a fifth metal layer 47, which becomes the word line WL in a third layer, is formed by performing a process similar to the process illustrated in the above-described FIGS. 10D to 10G, as illustrated in FIG. 10I, the first laminated body 28 in the bit line interconnecting portion 24 connected to the bit line BL in a second layer is formed. The first to fourth metal layers 41, 44 to 46 are laminated in the first laminated body 28, and the first laminated body 28 is formed at a position far from the memory cell area 21 in comparison with the first laminated body 28 connected to the bit line BL in a first layer.

FIG. 10I illustrates an example, as illustrated in FIG. 8, in which the word line interconnecting portions 25 are collected on one side of the memory cell area 21. After that, the first laminated body 28 for the bit line BL in each layer is sequentially formed in the bit line interconnecting area 22 in the same process.

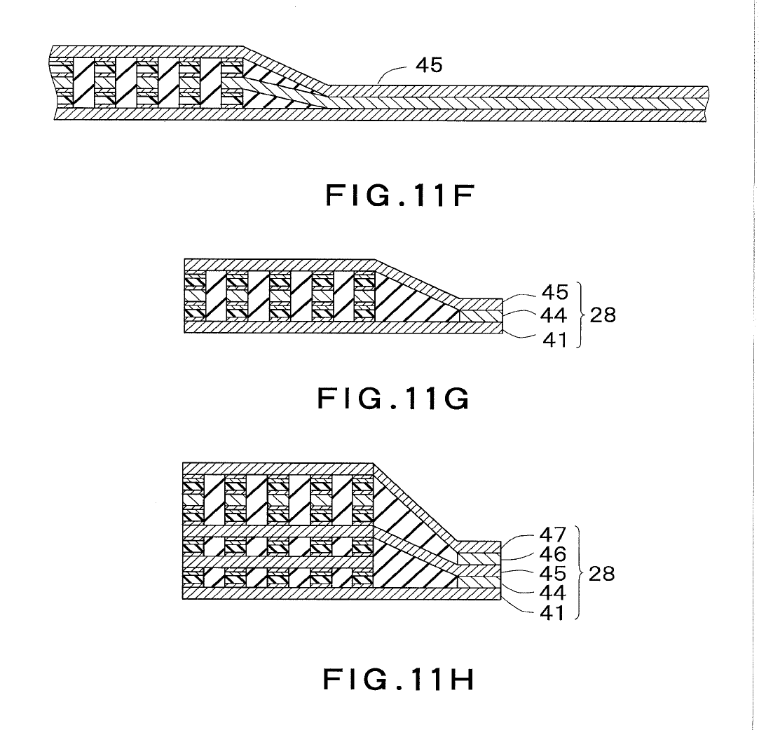

FIGS. 11A to 11H are views describing a manufacturing process for the word line interconnecting portion 25. The word line interconnecting portion 25 can be formed together in a process for forming the memory cell 11 as with the above-described bit line interconnecting portion 24.

First, in FIG. 11A, the above-described memory cell layer 10 is formed on the first metal layer 41 for the word line WL. Next, as illustrated in FIG. 11B, the dummy metal layer 42 is formed on the memory cell layer 10, and also the interlayer insulating film 43, in which a surface is inclined, is formed between the memory cell area 21 and the word line interconnecting area 23.

Next, as illustrated in FIG. 11C, the second metal layer 44 for the bit line BL is formed on the dummy metal layer 42 and the interlayer insulating film 43. The second metal layer 44 is closely arranged on the first metal layer 41 in the word line interconnecting area 23. Next, as illustrated in FIG. 11D, the memory cell layer 10 in a second layer is formed on the second metal layer 44 in the memory cell area 21.

Next, as illustrated in FIG. 11E, the dummy metal layer 42 is formed on the memory cell layer 10 in a second layer, patterning is performed by applying a resist (not illustrated) on the dummy metal layer 42, and the memory cells 11 in first and second layers are formed. Further, the interlayer insulating film 43, in which a surface is inclined, is formed between the memory cell area 21 and the word line interconnecting area 23.

Next, as illustrated in FIG. 11F, on the third metal layer 45 for the word line WL in a second layer is formed on the memory cell 11 in the second layer and the interlayer insulating film 43. The third metal layer 45 is closely arranged on the second metal layer 44 in the word line interconnecting area 23.

Next, as illustrated in FIG. 11G, the word line interconnecting portion 25 connected to the word line WL in a first layer is formed in the word line interconnecting area 23. The word line interconnecting portion 25 is the first laminated body 28 having a three-layer structure in which the first metal layer 41, the second metal layer 44, and the third metal layer 45 are laminated. The third metal layer 45 is connected to the word line WL in a second layer.

Then, by repeating the above-described processes illustrated in FIGS. 11D to 11G, as illustrated in FIG. 11H, the above-described first laminated body 28 has a five layer structure including the first to fifth metal layers 41, 44 to 47, and the fifth metal layer 47 in the highest layer is connected to the word line WL in a third layer.

FIG. 11H illustrates an example, as illustrated in FIG. 9, in which the word line interconnecting portions 25 are collected on one side in the memory cell area 21. After that, an interconnecting portion of the word line WL in each layer is provided in the common first laminated body 28 in the same process.

In the above-described embodiment, the bit line BL in each layer is separately connected to the first laminated body 28. However, the word line WL in each layer may be separately connected to the first laminated body 28. Further, the bit line BL in each layer may be connected to the common first laminated body 28. Specifically, structures of the first laminated bodies 28 in the bit line BL and the word line WL may be reversed. Furthermore, both of the bit line BL and the word line WL are separately connected to the first laminated bodies 28 for each layer. Alternatively, both of the bit line BL and the word line WL may be connected to the first laminated body 28 common for each layer.

The first laminated body 28 in the above-described bit line interconnecting area 22 is, for example, connected to a contact (not illustrated) extending to a lower side from the bit line interconnecting area 22. This contact is connected to a conductive layer (not illustrated) formed on a semiconductor substrate (not illustrated) and connected to an electrode pad (not illustrated) via the conductive layer. A separate contact may be provided between the above-described conductive layer and electrode pad.

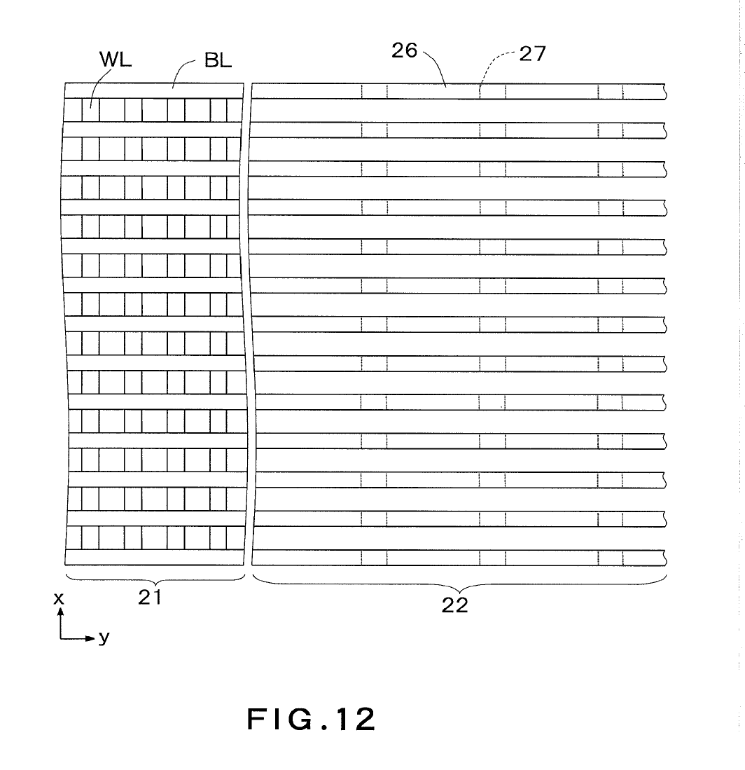

FIG. 12 is a plan view of the bit line interconnecting area 22. The plan view illustrated in FIG. 12 corresponds to FIG. 8. Specifically, FIG. 12 is a plan view of a right half side of FIG. 8, seen from an upper side.

The first conductive portion 26 extending from the memory cell area 21 to the bit line interconnecting area 22 is, as illustrated in FIG. 8, provided for each of the bit lines BL vertically laminated , and is vertically overlapped when seen from an upper side, as illustrated in FIG. 12. In FIG. 12, the second conductive portion 27 connected to the first conductive portion 26 connected to each of the bit lines BL vertically laminated is indicated by broken lines.

A contact (not illustrated) is arranged directly under each of the second conductive portions 27 illustrated in FIG. 12, and a bit line is driven via the contact.

The plan view illustrated in FIG. 12 is an example. Arrangement of the first conductive portion 26 and the second conductive portion 27 in the bit line interconnecting area 22 can be variously changed. Further, arrangement of the third conductive portion 29 and the fourth conductive portion 30 in the word line interconnecting area 23 can be variously changed.

In this manner, in the embodiment, at least either of the laminated bit lines BL or word lines WL (hereinafter called a first wire) is electrically conducted separately with first laminated bodies 28 for each layer. The first laminated body 28 has a structure in which metal layers for the bit lines BL and the word lines WL are laminated. Accordingly, the first laminated body 28 can be formed together in a process for laminating the memory cells 11 in the memory cell area 21, and therefore a separate manufacturing process for forming the first laminated body 28 is not needed. Further, the first laminated body 28 with less laminations, connected to the first wire on a lower side is arranged near the memory cell area 21. The first laminated body 28 with many laminations, connected to the first wire on an upper side is arranged as the memory cell area 21 becomes more distant. Therefore, multiple first laminated bodies 28 can be efficiently arranged, and a size of an interconnecting area can be reduced.

Regarding either of the laminated bit lines BL or word lines WL (hereinafter called a second wire), by connecting multiple second wires in different layers to the common first laminated body 28, a small number of the first laminated bodies 28 can be electrically conducted with multiple second wires in a laminating direction, and the size of the interconnecting area can be also reduced.

Although multiple embodiments according to the present invention have been described, these embodiments are presented as examples and are not intended to limit the scope of the invention. These new embodiments can be performed in other various modes, and can be omitted, replaced and changed variously without departing from the gist of the invention. These embodiments and variations thereof are included in the gist and scope of the invention and included in the invention described in claims and a scope equivalent thereto.

1. A resistance variable memory, comprising:
a memory cell area arranged on a substrate;
a plurality of first wires arranged at intervals in a first direction in the memory cell area and arranged at intervals in a laminating direction;
a plurality of second wires arranged at intervals in a second direction in the memory cell area and alternatively arranged with the first wires in a laminating direction;
memory cells which are arranged at each crossing point between the first wire and the second wire in the memory cell area and include variable resistance elements;
a first wire interconnecting area arranged separately from the memory cell area on the substrate and in which conductive layers electrically conducting with the plurality of first wires are arranged; and
a second wire interconnecting area arranged separately from the memory cell area on the substrate and the first wire interconnecting area and in which conductive layers electrically conducting with the plurality of second wires are arranged,
wherein the first wire interconnecting area comprises the plurality of first wire interconnecting portions electrically conducting with each of the plurality of first wires, and
wherein each of the plurality of first wire interconnecting portions comprises a first laminated body including a first conductive portion electrically conducting with a corresponding first wire, and a second conductive portions including conductive layers for a total number of the second wires and the first wires arranged on the substrate side from the corresponding first wire.

2. The resistance variable memory according to claim 1, wherein the conductive layers in the second conductive portion have the same thickness as thicknesses of the corresponding first or second wire.

3. The resistance variable memory according to claim 1, wherein the plurality of first wire interconnecting portions comprises the plurality of first laminated bodies separately arranged in the first direction and the plurality of first laminated bodies separately arranged in a direction in which the plurality of first wires extend.

4. The resistance variable memory according to claim 3, wherein the first laminated body arranged closer to the memory cell area in the plurality of first laminated bodies separately arranged in a direction in which the plurality of first wires extend electrically conducts with the first wire on a lower side in the memory cell area.

5. The resistance variable memory according to claim 3, wherein each of the plurality of first laminated bodies arranged at an equal distance from the memory cell area electrically conducts with the corresponding first wire on the same layer in the memory cell area.

6. The resistance variable memory according to claim 3, wherein the first wire interconnecting area is arranged on both sides in a direction that the plurality of first wires extend, across the memory cell area.

7. The resistance variable memory according to claim 6, wherein the first wire interconnecting area on one side comprises the plurality of first wire interconnecting portions electrically conducting with the first wires of odd-numbered layers laminated in the memory cell area, and the first wire interconnecting area on the other side comprises the plurality of first wire interconnecting portions electrically conducting with the firs wires of even-numbered layers laminated in the memory cell area.

8. The resistance variable memory according to claim 1, wherein the second wire interconnecting area comprises at least one second wire interconnecting portion electrically conducting with two or more second wires of the plurality of second wires, and wherein the second wire interconnecting portion comprises a second laminated body including a third conductive layer electrically conducting with the two or more second wires, and a fourth conductive layer including the same number of conductive layers as a total number of the second wires and the first wires other than the two or more first wires arranged on the substrate side from the two or more first wires.

9. The resistance variable memory according to claim 8, wherein the second wire interconnecting area is arranged on both sides in a direction that the plurality of second wires extend, across the memory cell area.

10. The resistance variable memory according to claim 9, wherein the second wire interconnecting area on one side comprises the second wire interconnecting portion electrically conducting with the second wires of the odd-numbered layers laminated in the memory cell area, and the second wire interconnecting area on the other side comprises the second wire interconnecting portion electrically conducting with the second wires of even-numbered layers laminated in the memory cell area.

11. The resistance variable memory according to claim 1, wherein the second wire interconnecting area comprises a plurality of second wire interconnecting portions electrically conducting with each of the plurality of second wires, and each of the plurality of second wire interconnecting portions comprises a second laminated body including a third conductive layer electrically conducting with a corresponding second wire, and a fourth conductive layer including the same number of conductive layers as a total number of the third wires and the second wires arranged on the substrate side from the corresponding second wire.

12. The resistance variable memory according to claim 1, wherein one side of the first wire and the second wire is a bit line and the other side is a word line.

13. A method for manufacturing a resistance variable memory, comprising:
forming a first conductive layer of a first layer on a substrate;
forming a first memory cell layer on the first conductive layer in a memory cell area on the substrate;
forming a memory cell of a first layer by patterning the first conductive layer and the first memory cell layer, and forming a first interlayer insulating film from the end of the memory cell area to the end on the memory cell area side in a first wire interconnecting area on the substrate;
forming the second conductive layer on the memory cell area and the first interlayer insulating film, and closely laminating the first and second conductive layers in the first wire interconnecting area;
forming a second memory cell layer on the second conductive layer in the memory cell area;
forming a second interlayer insulating film from an end of the second memory cell layer to an end of the memory cell area side of the first wire interconnecting area on the substrate;
forming a third conductive layer on the second memory cell layer and the second interlayer insulating film, and closely laminating the first or third conductive layer in the first wire interconnecting area;
forming the third memory cell layer on the third conductive layer in the memory cell area; and
forming memory cells of second and third layers by patterning the second conductive layer, the second memory cell layer, the third conductive layer, and the third memory cell layer, and forming a first laminated body in which the first conductive layer and the second conductive layer are closely laminated in the first wire interconnecting area.

14. The manufacturing method according to claim 13, wherein the first laminated body electrically conducting with a conductive layer on an upper layer side in the memory cells laminated on upper and lower sides of the memory cell in the memory cell area is formed at a farther distance from the memory cell area, as the number of laminations in the memory cell area increases.

15. The manufacturing method according to claim 13, comprising:
forming the second memory cell layer on the first conductive layer in the memory cell area after forming the first memory cell on the first conductive layer;
forming memory cells of first and second layers by patterning the first memory cell layer, the second conductive layer, and the second memory cell layer, and forming a third interlayer insulating film from an end of the memory cell area to an end of the memory cell area side in the second wire interconnecting area on the substrate;
forming the third conductive layer on the memory cell area and the third interlayer insulating film, and closely laminating the first or third conductive layer in the second wire interconnecting area; and
forming a second laminated body by patterning the first or third conductive layer in the second wire interconnecting area.

16. The manufacturing method according to claim 15, wherein a number of conductive layers connected to the second laminated body from an upper layer or a lower layer on memory cells laminated in the memory cell area increases as the number of laminations in the memory cell area increases.
